(19) United States
(12) Patent Application Publication
(10) Pub. No.: US 2021/0125957 A1
(43) Pub. Date: Apr. 29, 2021

(54) METHOD FOR FABRICATING AN ELECTRONIC DEVICE

(71) Applicant: COMMISSARIAT À L'ENERGIE ATOMIQUE ET AUX ENERGIES ALTERNATIVES, Paris (FR)

(72) Inventor: Jean BRUN, Grenoble (FR)

(73) Assignee: COMMISSARIAT À L'ENERGIE ATOMIQUE ET AUX ENERGIES ALTERNATIVES, Paris (FR)

(21) Appl. No.: 17/257,651

(22) PCT Filed: Jul. 4, 2019
(86) PCT No.: PCT/EP2019/067944

§ 371 Date: Jan. 4, 2021

(30) Foreign Application Priority Data
Jul. 4, 2018 (FR) 1856171

(51) Int. Cl. H01L 23/00

(52) U.S. Cl. CPC H01L 24/83; H01L 2224/80035; H01L 24/92; H01L 24/32; H01L 24/03; H01L 2224/9202; H01L 2224/9211; H01L 2224/73215; H01L 2224/92147; H01L 2224/83007; H01L 2224/8385; H01L 2224/26122; H01L 2224/83121; H01L 2224/32505; H01L 2224/32145; H01L 2224/32148; H01L 2224/03849; H01L 24/73

(57) ABSTRACT

The method for fabricating a device includes the following successive steps: providing a first substrate made from silicon of (100), (110) or (111) orientation, from a material of III-IV type or from a material of II-VI type, provided with at least one salient metal pad, and providing a second substrate; fixing the first substrate with the second substrate, the at least one metal pad forming a blocking means preventing movement beyond a threshold position; and performing an anneal of the metal pad so as to melt the metal pad and eliminate the blocking means.

### BACKGROUND OF THE INVENTION

The invention relates to a method for fabricating an electronic device and for example an integrated circuit chip.

### STATE OF THE ART

Numerous documents describe fabrication of electronic devices such as integrated circuit chips that are formed by association of two individual chips defining two different functions or of a chip associated with a counter-chip delivering electric power or only having a mechanical action. For example, the chip can comprise lateral grooves electrically and mechanically connected to electrically conducting wires.

U.S. Pat. No. 8,723,312 describes different chip architectures. These chips comprise a first substrate separated from a second substrate by a spacer. The spacer, first substrate and second substrate define one or two lateral grooves that are used to perform embedding of an electrically conducting wire.

The document WO2008/025889 describes a microelectronic chip comprising two parallel main surfaces and opposite lateral surfaces. At least one of the lateral surfaces comprises a groove provided with an electric connection means forming a housing for a wire-like element having an axis parallel to the longitudinal axis of the groove. U.S. Pat. No. 8,723,312 also describes a method for inserting a wire-like element in the groove.

The integrated circuit that is present in the first substrate is placed in electric contact with an external element by means of the electrically conducting wire that is inserted in the groove.

It is apparent that considerable constraints exist on the dimensions of the chip and in particular on the dimensions of the grooves in order to be able to embed the electrically conducting wires easily and in sustainable manner. Other alignment problems are also present in other fields and in particular in the micro electromechanical systems.

### OBJECT OF THE INVENTION

The invention proposes to provide a method for fabricating a device that is easy to implement and that enables a device to be achieved presenting better performances due to the fact that the positions of the components are better defined.

The method for fabricating a device is remarkable in that it comprises the following successive steps:
providing a first substrate made from silicon of (100), (110) or (111) orientation, or from a material of III-IV type or from a material of II-VI type, provided with at least one salient metal pad, and providing a second substrate;
fixing the first substrate with the second substrate, the at least one metal pad forming a blocking means configured to come into contact with the second substrate when the second substrate reaches a threshold position with respect to the first substrate;
performing an anneal of the metal pad so as to melt the metal pad and eliminate the blocking means.

In one development, the first substrate is fixed to the second substrate by means of a spacer, and when fixing of the first substrate with the second substrate is performed, the at least one metal pad is arranged to block movement of the first substrate with respect to the second substrate at a predefined separating distance in a direction perpendicular to a surface of the first substrate facing a surface of the second substrate.

In advantageous manner, after the blocking means have been eliminated, a portion of the second substrate is movable with respect to the first substrate.

In an alternative embodiment, the metal pad is formed on a first electrode and the anneal transforms the at least one metal pad into an additional electrode electrically connected to the first electrode.

In a particular embodiment, the method comprises a compression step of the spacer when fixing of the first substrate with the second substrate is performed so as to place the second substrate in contact with the at least one metal pad.

Advantageously, when fixing of the first substrate with the second substrate is performed, the at least one metal pad is arranged to block movement of the first substrate with respect to the second substrate in a direction parallel to a surface of the first substrate supporting the second substrate, the second substrate having flat side walls.

Preferentially, the metal pad is formed on an electric contact, the anneal transforming the metal pad into an additional electric contact, and an electronic component is fixed to the first substrate and is electrically connected to the first substrate by means of the additional electric contact.

It is advantageous to provide for the first substrate to be fixed to the second substrate by means of a spacer, the first substrate, spacer and second substrate defining at least one lateral groove and, when fixing of the first substrate with the second substrate is performed, the at least one metal pad is arranged to block movement of the first substrate with respect to the second substrate in a direction parallel to a surface of the first substrate supporting the second substrate, the at least one metal pad preventing insertion of a wire-like element in the lateral groove, and the anneal transforming the metal pad before a wire-like element is inserted in the lateral groove.

In an advantageous embodiment, the metal pad is formed on an electric track, the anneal transforming the metal pad into an electric contact. The wire-like element is electrically conducting and is electrically connected to the electric track by means of the electric contact.

In one development, a wire-like element is installed on the first substrate between two metal pads so that the two metal pads block movement of the wire-like element in a direction parallel to a surface of the first substrate supporting the wire-like element. When annealing of the two metal pads is performed, the molten material partially covers the wire-like element by capillarity.

In a particular embodiment, a fixing layer is deposited on the wire-like element and the metal material after the annealing step to secure the wire-like element with the first substrate.

It is advantageous to provide for the wire-like element to be installed on a support and for the first substrate to block the wire-like element against the support, the wire-like element being blocked during the annealing step.

Preferentially, the first substrate is fixed to the second substrate by means of a spacer. When fixing of the first substrate with the second substrate is performed, the at least one metal pad is constrained between the first and second substrates, the spacer, the first substrate and second substrate defining a channel sealed off by the at least one metal pad. The annealing step makes the at least one metal pad change to molten state to open the channel.

### BRIEF DESCRIPTION OF THE DRAWINGS

Other advantages and features will become more clearly apparent from the following description of particular embodiments given for non-restrictive example purposes only and represented in the appended drawings, in which:

FIGS. 1 to 5 represent a first embodiment of a method for fabricating an integrated circuit chip, in schematic manner, in cross-section,

FIG. 6 represents an alternative embodiment of a method for fabricating an integrated circuit chip, in schematic manner, in cross-section,

FIGS. 7 to 10 represent a second embodiment of a method for fabricating an integrated circuit chip, in schematic manner, in cross-section,

FIGS. 11 to 15 represent a third embodiment of a method for fabricating an electronic device, in schematic manner, in cross-section,

FIGS. 16 to 19 represent a fourth embodiment of a method for fabricating an electronic device, in schematic manner, in cross-section,

FIGS. 20a to 23a and 20b to 23b represent a fifth embodiment of a method for fabricating a device, in schematic manner, respectively in cross-section and in top view.

### DETAILED DESCRIPTION

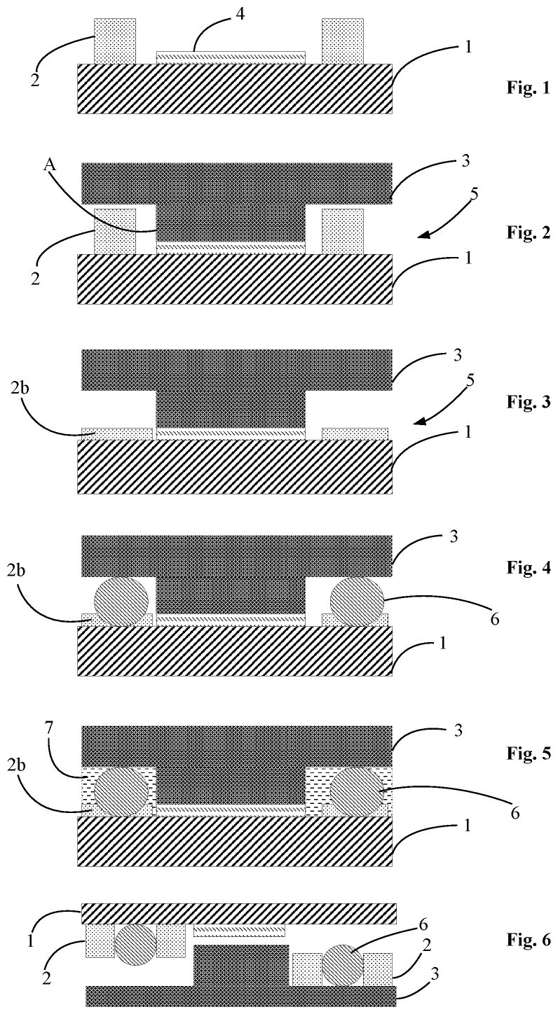

As illustrated in the different embodiments and in particular in FIGS. 1 to 19, it is particularly advantageous, when fabricating an electronic and/or microfluidic device, to use blocking means in order to fabricate the device more easily or to improve its performances.

When fixing of a first substrate to a second substrate is performed, it is advantageous to use blocking means so as to define a position or a range of accessible positions for the second substrate with respect to the first substrate. The blocking means can also be used to define the position of other components of the electronic device, for example wire-like elements fixed to the first substrate and/or to the second substrate.

However, in order to have devices that are as small as possible, it is particularly advantageous to use blocking means that are sacrificial so that, after the required alignment/positioning has been fixed, the blocking means are removed to allow the freed surface to be used for another function. It is particularly advantageous for removal of the blocking means to constitute a transformation of the blocking means into another function, for example an electrode, an electric contact or a fixing means.

It is then particularly advantageous for the blocking means to be formed by at least one metal pad that can be annealed so that it melts. The metal pad is initially shaped so as to define the blocking means and the annealing step enables the shape of the blocking means to be changed. By changing shape, the pad is no longer able to perform the blocking function but it procures another advantage for example by covering a wire-like element thereby improving the electric contact and/or the mechanical strength.

As illustrated in FIGS. 1 to 10, the chip is defined by means of a first substrate 1 capped by at least one metal pad 2. First substrate 1 is designed to be fixed to a second substrate 3.

In one configuration, pad 2 acts so as to define the position of second substrate 3 with respect to first substrate 1 in one or more directions that are parallel to the two facing surfaces of substrates 1 and 3. In another configuration illustrated in FIGS. 10 to 18, pad 2 acts so as to define the distance separating the two substrates 1 and 3, i.e. pad 2 fixes the separating distance or gap between second substrate 3 and first substrate 1 in a direction perpendicular to the two facing surfaces of substrates 1 and 3.

Pads 2 present a certain advantage for aligning the two substrates 1 and 3 or for defining a separating gap between the two substrates, but they do occupy a non-negligible volume at the surface of substrates 1 and 3 which limits their use or makes it necessary to work with larger substrates.

It is therefore particularly advantageous to use sacrificial pads 2. However, the removal step may have a non-negligible influence on the different components that are already present at the surface of first and second substrates 1 and 3. For example the use of a particular etching atmosphere makes it necessary to protect areas of substrates 1 and 3 that are reactive to this atmosphere or makes it compulsory to use a larger thickness of material in order to anticipate a more or less large removal of material when pad 2 is eliminated. Plasma etching or chemical etching may also impair components that may be located in the cavity. In a configuration with a closed cavity, the inside of the cavity is inaccessible, which can be the case for a pressure sensor whose membrane is thinned at the end of the process. It is therefore particularly advantageous to provide for the transformation step of pad 2 to be a thermal transformation step by increasing the temperature of pad 2 to beyond its melting temperature. For example, heating takes place by Joule effect by making a current flow in metal pad 2.

It is also advantageous not to use an elimination step of pad 2 for example by chemical or physical process but on the contrary a transformation step of pad 2 so that the material that formed pad 2 can subsequently interact with another component of the electronic device and perform another function. It is advantageous to use a pad 2 made from electrically conducting material. Initially, pad 2 performs positioning of first substrate 1 with respect to second substrate 3 in mechanical manner. After transformation of the pad, the position of second substrate 3 is defined with respect to first substrate 1 and the electrically conducting material is used to electrically connect first substrate 1 with an external component that is preferentially inserted after the two substrates 1 and 3 have been fixed.

The volume occupied by first pad 2 is freed enabling an additional element to be inserted. Furthermore, it is particularly advantageous to provide for the additional element to be fixed to first substrate 1 while the material forming pad 2 is still in liquid state following the transformation step. The additional element can thus be inserted without the conducting material hampering installation on first substrate 3. In advantageous manner, pad 2 prevents installation of the additional element thereby making monitoring of the fabrication method easier by preventing an inversion of the steps.

As an alternative, the material forming pad 2 is transformed and then solidifies and the additional element is installed. A new annealing step can be applied so that the material forming pad 2 reverts to molten state to react with the additional element.

The additional element is for example an electrically conducting wire-like element 6 or an electronic component 9.

In a first embodiment, the fabrication method comprises provision of a first substrate 1 capped by one or more salient pads 2 as illustrated in FIG. 1. First substrate 1 is designed to come into contact with a spacer A capping a second substrate 3.

In the fabrication method of the chip, the assembly formed by spacer A and second substrate 3 is placed in contact with first substrate 1. A first alignment is performed in the X and/or Y directions so as to judiciously place spacer A with respect to first substrate 1 thereby defining one or more lateral grooves 5 and ensuring that first substrate 1 is correctly placed facing second substrate 3. This placing of spacer A with respect to first substrate 1 is called assembly step. First substrate 1 is arranged on second substrate 3 with a first alignment. This first alignment can be defined in a first direction X and possibly a second direction Y perpendicular to the first direction X. The first and second directions are taken in a plane parallel to the surface of first substrate 1.

After the assembly step, a fixing step is performed so as to fix first substrate 1 with spacer A and to fix first substrate 1 with second substrate 3. When the two substrates are secured to one another, a pressure stress is applied on first substrate 1 and on second substrate 3 resulting in a possible displacement of first substrate 1 with respect to second substrate 3 by sliding. The first alignment is impaired or even lost. This displacement is linked for example to an adhesive layer 4 located between first substrate 1 and spacer A. Adhesive layer 4 performs fixing of first substrate 1 with second substrate 3. Just before adhesion takes place, layer 4 is transformed and generally liquefies encouraging sliding between spacer A and first substrate 1. Sliding results in a modification of the dimensions of the lateral grooves. For example, second substrate 3 is fixed to first substrate 1 by a layer of polymer material 4. Preferentially, the at least one metal pad 2 is formed from a material having a melting temperature that is lower than the degradation temperature of polymer material layer 4.

To prevent displacement of spacer A when the latter is secured with first substrate 1, blocking means are placed on first substrate 1. The blocking means are formed by at least a first pad 2 salient with respect to the surface of first substrate 1 so as to come into contact with spacer A and to restrain movement thereof at least in the first direction X and advantageously in the second direction Y. The end stop that exists to limit movement in the X direction and/or Y direction ensures a minimal connection surface between spacer A and first substrate 1 and therefore a certain adhesive strength. This also ensures a minimal cross-section for groove 5.

First pad 2 can be of any shape. It is advantageous to use a plurality of different pads 2 so as to form a plurality of stops that serve the purpose of limiting movement of spacer A in the X and/or Y directions.

It is also possible to use a single pad 2 that is arranged to limit the movement of spacer A in the X and/or Y directions. Pad 2 can surround the mechanical contact area between spacer A and first substrate 1. As an alternative, pad 2 can be C-shaped or L-shaped so as to limit movement of spacer A in the X and Y directions and in one or two opposite directions in each direction. In one configuration, pad or pads 2 are arranged to block movement of the spacer only in the X direction or only in the Y direction.

In the embodiment illustrated in FIG. 1, adhesive layer 4 is advantageously deposited on first substrate 1 so as to secure spacer A with first substrate 1. In more general manner, adhesive layer 4 can be placed on first substrate 1 and/or on spacer A. Depending on the embodiments, adhesive layer 4 can be deposited before or after pads 2 are formed. Adhesive layer 4 has a reaction temperature enabling fixing of substrates 1 and 3 that is lower than the transformation temperature of pad 2.

In the embodiment illustrated in FIG. 3, spacer A, first substrate 1 and second substrate 3 define at least one lateral groove 5.

Pad 2 can present a large thickness to define the height of the groove and to avoid adhesive layer 4 being crushed too much by spacer A.

After the two substrates have been fixed to one another, in order to functionalise lateral groove 5 by installing for example a wire-like element 6 therein, it is particularly advantageous to eliminate pads 2 that partially fill groove 5 and prevent easy access to groove 5. As illustrated in FIG. 3, an annealing step is used to transform pad 2 thereby freeing a part of the volume of lateral groove 5. Pad 2 is transformed into an electric contact 2b of smaller thickness than the initial pad 2.

In the embodiment illustrated in FIG. 3, the height of pad 2 is reduced by means of the annealing step thereby facilitating insertion of a wire-like element 6.

It is particularly advantageous to provide for pad 2 to be formed from an electrically conducting material, for example from a metal material. Pad 2 is arranged on an electric track of first substrate 1 so that, after it has been transformed, the electrically conducting material forms an electric contact between wire-like element 6 and the electric track of first substrate 1.

In advantageous manner, the molten pads participate in fixing of the wire-like elements which are electrically conducting wires 6 with first substrate 1 and in improvement of the electric connection between electrically conducting wire 6 and the electric track. Pads 2 are formed from an electrically conducting material ensuring the electric contact between electrically conducting wire 6 and the integrated circuit of first substrate 1.

In advantageous manner, pad 2 comprises or is formed by a brazing material that is configured to melt and cover electrically conducting wire 6 by capillarity in order to enhance the adhesion between the chip and electrically conducting wire 6. In a preferential embodiment, pad 2 is achieved by means of several electrically conducting materials.

In a particularly advantageous embodiment, pad 2 extends beyond the first electric contact area formed by the electric track situated in groove 5.

When electrically conducting wires 6 are inserted hot in lateral grooves 5 of the chip, the metal material is in liquid state and wets electrically conducting wire 6 by capillarity thereby increasing the electric contact surface between first substrate 1 and electrically conducting wire 6. As an alternative, if the height of the spacing between pad 2 and substrate 3 allows, wire 6 is inserted in groove 5 and pad 2 is then melted.

It is advantageous to provide a brazing material that presents a higher melting temperature than the temperature used during the fixing step of spacer A with first substrate 1.

Once wire-like element 6 has been installed in lateral groove 5, it is advantageous to deposit an encapsulation material 7. As illustrated in FIG. 5, the volume initially occupied by a part of pad 2 is left free. This new free space can subsequently be filled by an encapsulation material 7 for example an adhesive that will enhance the adhesion between first substrate 1 and second substrate 3 and with spacer A and wire-like element 6. In advantageous manner, encapsulation material 7 is configured to fill the free areas and to reinforce the solidity of the chip. In a particular embodiment, encapsulation material 7 is a glue and advantageously a structural glue which can be an E505 glue marketed by EPO-TEK. It is also possible to use Parylene also called poly(p-xylylene) or a fusible glass.

As a variant, encapsulation material 7 can be a barrier material which is configured to prevent the passage of pollutants, for example water. In a particular embodiment, encapsulation material 7 is a glue and advantageously a protection glue which can be a TC420 glue marketed by POLYTEC. It is further possible to use an encapsulation material 7 performing both these functions: adhesive and barrier.

In advantageous manner, the length of spacer A in the X direction is a few hundred microns, for example between 100 microns and 1 millimetre. The width of spacer A in the Y direction is advantageously a few tens of microns, for example between 10 microns and 100 microns.

Depending on the embodiments, pads 2 formed on first substrate 1 are produced by electrolytic growth or by screen printing. Other techniques are also available but are less practical from an industrial point of view. It is possible to provide for a part of the pads to be formed by electrolytic growth and another part of the pads to be formed by another technique for example by screen printing.

In advantageous manner, pads 2 are salient from the surface of first substrate 1 by a height comprised between a few microns and a few hundred microns. For example, the height of pads 2 is comprised between 2 microns and 500 microns. The width of pads 2 is advantageously a few tens of microns, for example between 10 microns and 100 microns.

The chips as described can be integrated in garments to form smart fabrics due to their small size.

In a particular embodiment, first substrate 1 comprises one or more electronic circuits, for example one or more field effect transistors and/or bipolar transistors. Substrate 1 can also comprise one or more resistors and/or one or more capacitors. First substrate 1 can also be formed from semi-conductor materials, for example silicon of (100) (110) or (111) orientation, material of III-V type or material of II-VI type.

The first substrate advantageously comprises a support made from semi-conductor material capped by several layers of electrically insulating material inside which multiple electrically conducting tracks run in three dimensions. The second substrate and/or the spacer are fixed on an electrically insulating layer having one or more accessible electric tracks.

In an alternative embodiment, the material forming pads 2 is partially eliminated after second substrate 3 has been fixed. It is advantageous to anneal pads 2 so as to transform the material into liquid or molten state and to absorb the material that formed pads 2 by capillarity. As lateral groove 5 has been freed, it is possible to insert a wire-like element 6 therein for example by embedding.

The chip comprises two opposite external main surfaces. The first external main surface is formed by a first surface of first substrate 1. The second external main surface is formed by a first surface of second substrate 3. The two opposite external main surfaces are preferentially parallel. The chip preferentially comprises two main surfaces joined to one another by lateral surfaces. At least one groove 5 is present in one of the lateral surfaces. In the embodiment illustrated in FIGS. 2 to 5, two grooves 5 are formed and are separated by spacer A.

In advantageous manner, the general shape of the chip is that of a parallelepiped, the two external main surfaces then being able to be of substantially equal dimensions and being joined to one another by four lateral surfaces. Other chip shapes are naturally possible. For example, a first substrate 1 and/or second substrate 3 could be had presenting a convexly curved external main surface. Furthermore, a lateral surface can be the extension of a main surface, without precise demarcating edges between the two.

In a first embodiment, spacer A has been secured with second substrate 3, for example by binding. In an alternative embodiment, spacer A is formed by etching of second substrate 3. It is also possible to combine these two embodiments. Advantageously, spacer A presents a height comprised between 100 microns and 200 microns. The height of spacer A corresponds to the height of the salient part with respect to the rest of second substrate 3. The height of spacer A is defined according to the diameter of electrically conducting wires 6.

In a particular embodiment, spacer A is formed inside second substrate 3 by ion etching, preferentially by Reactive Ion Etching and more preferentially by Deep Reactive Ion Etching.

Location of second substrate 3 on first substrate 1 with the desired level of alignment can be obtained in industrial manner by means of bonding and alignment equipment marketed by Suss MicroTec and EVG.

In preferential manner, the fixing step is performed by bonding, melting of a fusible material, molecular sealing or anodic sealing of spacer A with first substrate 1.

In a particular embodiment, fixing is achieved by means of an anneal performed at maximum temperature comprised between the glass transition temperature and the polymerisation temperature of adhesive material 4 used to bind spacer A with first substrate 1. For example purposes, the adhesive material is a glue marketed under the brand name HT1010 by Brewer Science Inc.

Wire-like elements 6 are inserted longitudinally in grooves 5. Wire-like elements 6 are preferably mechanically pinched in grooves 5.

First substrate 1 comprises at least one functional block configured to perform at least one logic and/or analog function and possibly a mechanical function (cf. supporting electric wires . . . ). First substrate 1 also comprises at least a first electric contact area. In the illustrated embodiment, first substrate 1 comprises a second electric contact area. In advantageous manner, first substrate 1 comprises a silicon substrate or is constituted by a silicon substrate. In a particular embodiment, first substrate 1 is configured to perform a radio-identification function also called “radio frequency identification” or RFID. In advantageous manner, the functional block is an integrated circuit configured to perform at least one logic and/or analog function.

In an advantageous embodiment, first substrate 1 and second substrate 3 are configured to provide a plurality of chips. First substrate 1 comprises a plurality of identical or different integrated circuits that are advantageously repeated with a first repetition pitch in the first direction X and that are advantageously repeated with a second repetition pitch in the second direction Y.

Second substrate 3 is placed on first substrate 1 so as to form the plurality of chips comprising lateral grooves. Once the two substrates have been placed in contact and fixed to one another, a dicing step can be performed so as to dice first substrate 1, second substrate 3 and possibly spacer A thereby defining a plurality of chips and the lateral grooves. The chips can then be dissociated from one another.

In a first particular case, first substrate 1 comprises predefined weakened lines so as to define the dimensions of the different chips and facilitate the subsequent dicing. The same is the case for second substrate 3. It is then particularly advantageous to align first substrate 1 correctly with the assembly formed by spacer A and second substrate 3 in order to align the predefined weakened lines and facilitate dicing of the chips.

In a second particular case, first substrate 1 and/or second substrate 3 do not comprise predefined weakened lines. The chips are diced by any suitable technique, for example by means of a saw or a laser beam. In this particular case, first substrate 1 and second substrate 3 present identical dimensions in the first direction and in the second direction.

In one embodiment, second substrate 3 is an active element, i.e. it comprises an electronic component, for example a battery. Second substrate 3 can be configured to supply power to first substrate 1. As an alternative, second substrate 3 does not comprise an electronic component.

Each lateral groove comprises two opposite surfaces respectively formed by first substrate 1 and second substrate 3 and a base formed by spacer A. Each groove 5 is open at both ends. Each lateral groove 5 has an electric track on its first lateral surface. Preferentially, insertion of the wire-like element is performed via the lateral surface perpendicularly to the longitudinal axis of the groove.

Each wire-like element 6 presents a longitudinal axis that is parallel or substantially parallel to the longitudinal axis of groove 5, i.e. parallel to the Y axis. Each wire-like element 6 is secured to first substrate 1 by soldering with addition of material, by gluing, and/or by embedding. Embedding in groove 5 requires correct dimensioning of wire-like element 6 and groove 5. The strength by embedding may be insufficient and generally requires a reinforcement phase by addition of glue and/or metal by means of adhesive material 4.

Electrically conducting wires 6 can present any cross-section. Depending on the embodiments, first and second electrically conducting wires 6 are single-strand or multi-strand conducting wires. It is therefore possible to have a chip comprising two single-strand conducting wires or two multi-strand conducting wires or a mixture of these two technologies. A multi-strand conducting wire comprises several conducting wires that are electrically dissociated and that enable different signals to be conveyed. As an alternative, the multi-strand conducting wire comprises several conducting wires that are electrically connected to one another and convey the same electric signal. A multi-strand conducting wire can for example present the form of a strand of several electrically conducting wires. It is particularly advantageous to use a multi-strand conducting wire in association with the material of the pad in molten state as the molten material permeates into the gaps between the wires thereby improving the contact quality.

When the chip is a RFID chip, first and/or second electrically conducting wires 6 are advantageously configured to form communication antennas.

The height of spacer A and the cross-section of electrically conducting wires 6 are advantageously configured to ensure that the electrically conducting wires are compressed between the two substrates.

In another embodiment, first substrate 3 is capped by at least two pads 2 spaced apart from one another so as to allow insertion of a wire-like element 6.

Once wire-like element 6 has been installed, an anneal is performed so as to melt the pads which will permeate onto and/or into the wire-like element to at least partially cover the latter and fix it on the first substrate. Fixing can be improved by subsequently adding an adhesive 7 securing the wire-like element with first substrate 1.

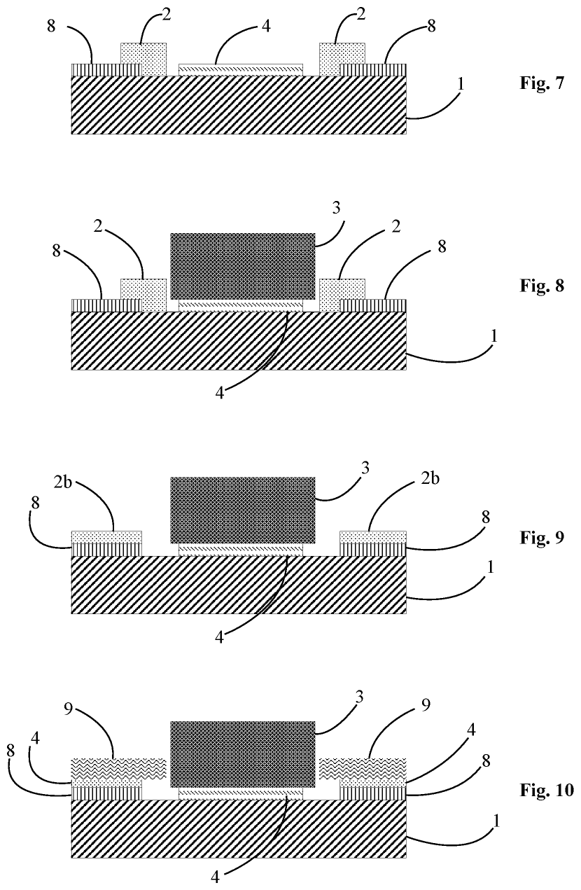

In an alternative embodiment illustrated in FIG. 6, wire-like element 6 is installed on the first substrate and the two pads 2 are arranged on second substrate 3 at a distance from wire-like element 6. Second substrate 3 is moved in the direction of first substrate 1 to wedge wire-like element 6 by means of the two pads 2.

An anneal is then performed so that the molten material forming the pads permeates onto wire-like element 6 to perform fixing and possibly enhance an electric connection.

In a second embodiment illustrated in FIGS. 7 to 10, the method for fabricating an electronic device also comprises the use of a sacrificial pad 2. The method is different from the previous method in that the second substrate does not enable lateral grooves 5 or grooves that can cooperate with wire-like elements 6 to be defined.

As illustrated in FIG. 7, first substrate 1 is associated with one or more electric contacts 8, for example made from metal, that are arranged salient from or on the surface of first substrate 1. One or more pads 2 are arranged on the surface of first substrate 1. It is also advantageous to use an adhesive layer 4 that can be deposited before or after pads 2. It should be noted that salient electric contacts 8 could also be used in the previous embodiment.

As illustrated in FIG. 8, a second substrate 3 is installed on first substrate 1. Second substrate 3 is designed to be fixed to first substrate 1 for example by means of adhesive layer 4. In the fixing step, pad or pads 2 act so as to limit misalignment between the two substrates 1 and 3. Second substrate 3 comprises flat side walls that are perpendicular or substantially perpendicular to the surface of first substrate 1.

It is always advantageous to at least partially eliminate pads 2 in order to take advantage of an additional surface area accessible on the surface of first substrate 1 to be able to integrate additional functionalities.

As illustrated in FIG. 9, an annealing step is applied to melt pad 2 and make electric contact or contacts 8 located at the surface of first substrate 1 accessible. These contacts were initially partially or completely covered by pads 2 which made them hardly usable. Once pad 2 has been transformed, it is possible to fix an electronic device 9 or an electric connector on electric contact 8 to ensure transmission of signals to an electronic device 9. The position of electronic device 9 can be partly fixed using the second substrate as end stop in a fixing step of electronic device 9 on first substrate 1.

In a particular configuration, the use of pads having a large thickness facilitates alignment of first substrate 1 with respect to second substrate 3. Pad 2 on the other hand prevents optimal placing of electronic device 9. The melting step frees a volume initially occupied by the pad thereby facilitating or authorising placing of device 9 as close as possible to substrate 3 or at a required height defined by the thickness of the pad after melting.

In the embodiment illustrated in FIG. 10, a first electronic component 9 and a second electronic component 9 are fixed on each side of second substrate 3 respectively on a first electric contact 8 and a second electric contact 8 salient from first substrate 1.

It is also possible to provide for an electronic component 9 to be fixed for example in the form of a ring surrounding second substrate 3.

In advantageous manner, second substrate 3 and/or electronic component and/or first substrate 1 can also comprise electronic functionalities or a battery.

The reverse configuration can naturally be achieved by installing pad 2 in place of substrate 3 of FIG. 7 and associating a second substrate 3 surrounding pad 2 so as to prevent any movement in the X direction and/or in the Y direction.

There again, it is particularly advantageous to provide for pad 2 to be made from electrically conducting material. When it undergoes transformation to liquid state, the material forming pad 2 covers the electric contact and makes the electric connection between the added electronic components 9 and first substrate 1. Such an embodiment is illustrated in FIGS. 9 and 10.

The materials and configurations described for the previous embodiments can also apply to this embodiment. It is advantageous to use an electric contact 8 made from copper or from copper and gold alloy or covered with gold or with a copper and gold alloy. The material forming pad 2 is preferably chosen so as to interdiffuse with the material forming electric contact 8. For example electric contact 8 is made from copper and pad 2 is made from gold.

In an advantageous embodiment, electric contact 8 has a larger span than necessary and the first substrate defines a plurality of locations for a plurality of second substrates. The electric contacts are cut when dicing of the substrate is performed to differentiate the multiple chips from one another.

It is also possible to provide for the volume used to form pad 2 to be larger than necessary to define the electric contact. A part of the electric contact formed by the molten pad can be eliminated by sawing or any other technique after the wire-like element or electronic component 9 has been installed.

It is also possible to combine these two embodiments by using a second substrate that defines one or more grooves and leaves other portions accessible to be able to install one or more electronic components 9.

It is advantageous to provide for the surface of the substrate to present areas having different surface coatings that are configured to modify the wettability of the material forming the pad in molten state. In this way, the pattern formed by the differences of surface coating makes it possible to at least partially define the pattern of the contact on the surface of the first substrate and the thickness of the molten material and therefore the thickness of the resulting electric contact. The coating difference can be obtained by applying a plasma treatment and/or by using different materials. The difference of treatment facilitates lateral extension of the molten material to reduce the thickness or on the contrary limits the lateral extension to increase the thickness thereby increasing the covering of the wire-like element. The surface can be formed by a first coating that preferentially attracts the material in molten state and by a second material that attracts the material in molten state to a lesser extent or even repels it to define the shape of the pattern after melting and its thickness. It is also possible to displace the pattern when melting takes place by using a suitable surface state or even by applying a gas flow.

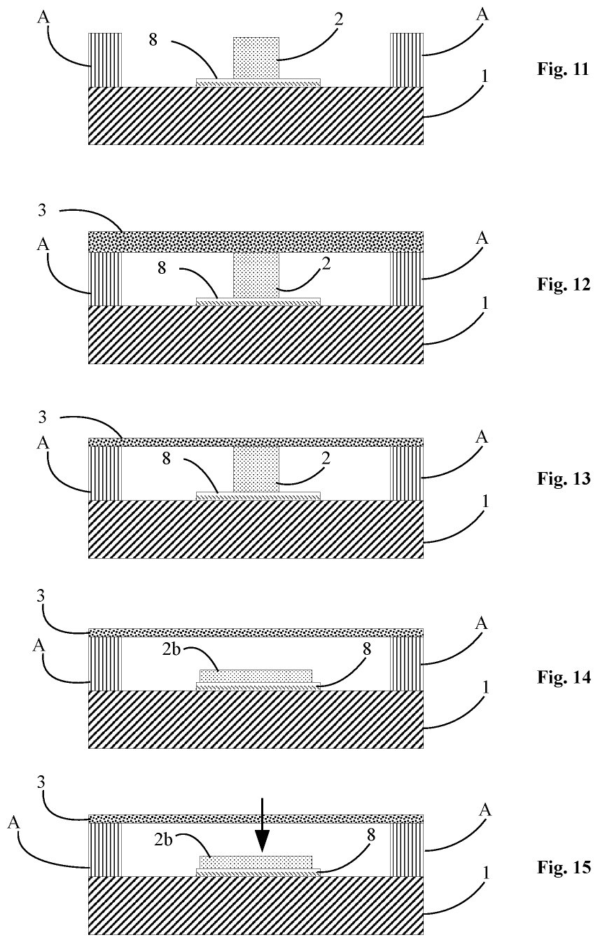

In another embodiment illustrated in FIGS. 11 to 15, at least one sacrificial pad 2 is used to define the position of second substrate 3 with respect to first substrate 1.

In the embodiment illustrated in FIG. 11, first substrate 1 is capped by at least one pad 2 advantageously located on an electric contact 8 for example in the form of an electrode.

As illustrated in FIGS. 11 to 15, one or more spacers A are formed on the surface of substrate 1. A second substrate 3 is fixed to first substrate 1 on the one or more spacers A. Second substrate 3 comes into contact with pad 2 thereby enabling the distance separating the two facing surfaces of substrates 1 and 3 to be defined.

In advantageous manner, first substrate 1, second substrate 3 and support A define a tightly sealed cavity. Spacer A is in the form of a ring for example made from polymer material. When second substrate 3 is fixed to spacer A, pad 2 supports second substrate 3 and prevents it from being deformed.

As illustrated in FIG. 12, second substrate 3 can undergo a technological thinning and/or planing step of its external surface. It is particularly advantageous to use second pad 2 which limits or prevents bending of second substrate 3 and facilitates treatment of second substrate 3. The risks of breaking and/or deformation of second substrate 3 are greatly reduced. It is also possible to provide for the substrate to undergo a thickening step or a deposition step of another material for example to form another electrode. Any technological step performed on the second substrate or in the presence of the second substrate can lead to breaking of the second substrate, for example when the pressure peak occurs.

It is particularly advantageous to use second substrate 3 as resonant element. The resonance frequency of second substrate 3 can then be defined by adjusting the thickness of second substrate 3. Planing and/or thinning and/or thickening of second substrate 3 enables the mechanical characteristics of the resonator to be precisely defined. It is advantageous to engineer the resonant element more easily by depositing a thicker and therefore less fragile material and by adjusting the final thickness to the required frequencies.

Once the thickness has been defined and advantageously towards the end of the fabricating method of the device, it is advantageous to apply an anneal that transforms pad 2 thereby releasing second substrate 3 which can move, for example which can vibrate.

There again, it is advantageous to use a pad 2 made from electrically conducting material which, after it has been transformed to molten state, will at least partially cover electrode 8 and participate in actuation of second substrate 3. Actuating electrode 8 is therefore partially formed by the electrically conducting material that served the purpose of defining the gap separating first substrate 1 and second substrate 3.

Second substrate 3 can be formed by any suitable material, for example glass or silicon, provided that the material forming second substrate 3 can withstand the transformation temperature of pad 2.

When the cavity is hermetically sealed, it is particularly inconvenient to use a pad 2 made from polymer material which will outgas when transformation thereof is performed thereby increasing the pressure in the cavity. It is particularly advantageous to use a pad 2 made from metal material that does not impede magnetic or electrostatic actuation of the vibrating element formed by second substrate 3.

Second substrate 3 is not necessarily a resonant element. It is possible to monitor the deformation of second substrate 3 to monitor the pressure difference between the two surfaces of the second substrate. It is also possible to monitor the atmosphere in the cavity by monitoring the electric capacitance value that exists between electrode 8 and second substrate 3. In all these applications, it is particularly advantageous to have a good mastery of the separating gap between second substrate 3 and electrode 8 to reduce the calibration operations and take advantage of a larger measurement range.

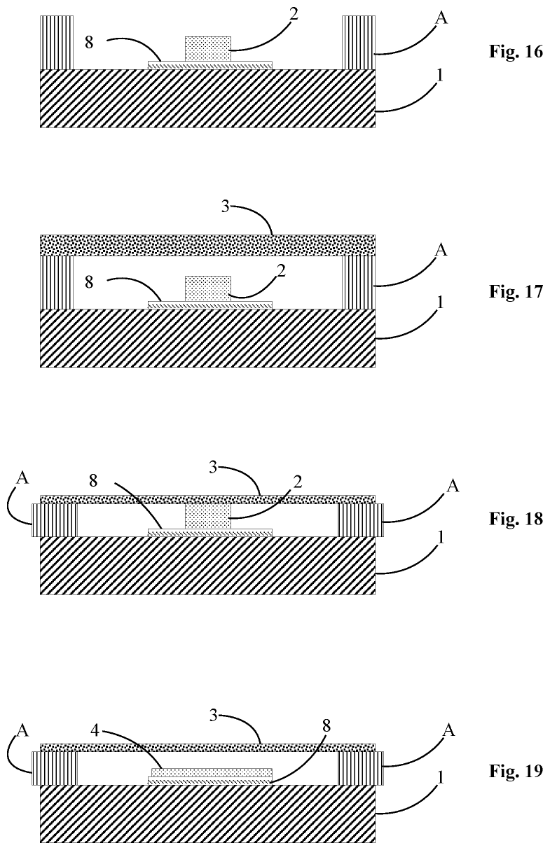

In another embodiment illustrated in FIGS. 16 to 19, the pad further enables the separating gap between the two substrates and therefore between electrode 8 and second substrate 3 to be defined.

As in the foregoing, first substrate 1 is capped by a pad 2 that is advantageously at least partially arranged on an electric contact 8. Electric contact 8 can be salient from first substrate 1. Spacer or spacers A present a greater height than that of the assembly formed by electrode 8 and pad 2.

As illustrated in FIG. 17, second substrate 3 is deposited at a distance from first substrate 1 pressing on the one or more spacers A. Second substrate 3 is situated at a distance from pad 2.

As illustrated in FIG. 18, it is then advantageous to apply a stress on the one or more spacers A, for example by means of second substrate 3, so as to bring second substrate 3 into contact with pad 2.

In this way, the thickness of pad 2 enables the gap separating first substrate 1 and second substrate 3 to be defined. When deformation of the spacers A is performed, a solidification treatment is applied on spacers A so that the distance separating the two substrates is kept after the stress has been removed.

The solidification treatment is for example a heat treatment which will result in polymerisation of a spacer A made from polymer material. It is also possible to provide for the solidification treatment to use a polymerisation by optic means, or by electronic means or by elimination of a solvent present in spacer A. After the solidification treatment, second substrate 3 is in contact with pad 2.

It is further possible to provide for spacer A to be made from metal.

Once second substrate 3 has been installed in the required position, pad 2 can be subjected to a thermal anneal that transforms pad 2 and frees second substrate 3. Transformation of pad 2 allows second substrate 3 to move with respect to first substrate 1. It is then possible to engage a vibration of second substrate 3.

As in the foregoing, it is particularly advantageous to use a pad 2 made from electrically conducting material so that the latter forms an actuating electrode of second substrate 3 after it has been transformed. There again, pad 2 makes it possible to define the gap between second substrate 3 and electrode 8 and to then actuate second substrate 3 or to monitor a physical distance between the electrode and the second substrate.

In the illustrated example, the height of pad 2 is identical to the height of spacer A so that substrate 3 is in equilibrium before the transformation step of pad 2. As an alternative, it is possible to stress substrate 3, for example by using a pad 2 having a larger height than the height of spacer A, but other configurations are possible.

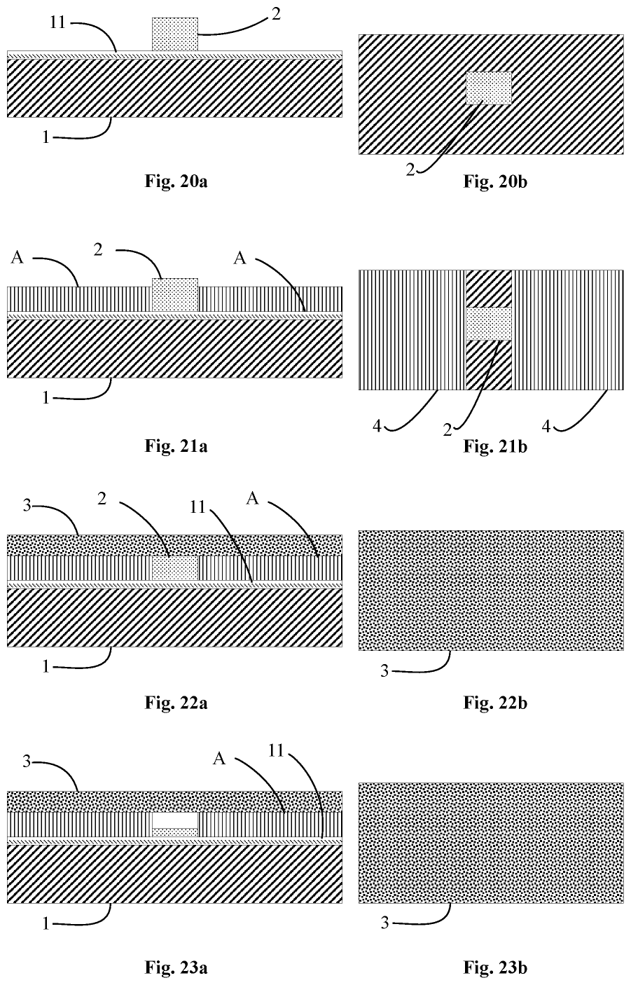

In another embodiment illustrated in cross-section in FIGS. 20a to 23a and in top view in FIGS. 20b to 23b, it is possible to form a device that defines a channel sealed by a pad 2.

As illustrated in FIGS. 20a and 20b, a pad 2 is formed on the surface of first substrate 1, for example on a covering layer 11. Two spacers A defining two side walls are then formed so as to define the two opposite side walls of a channel. The two side walls A are spaced apart from one another and come into contact with pad 2. In other words the two side walls A are separated from one another by a pad 2 and are separated by a distance equal to the width of pad 2.

Depending on the embodiments, the two side walls A can be formed before or after pad 2 is formed. However, it is preferable to form pad 2 before forming side walls A.

It is advantageous to provide for the thickness or height of pad 2 to be greater than the thickness or height of side walls A.

Second substrate 3 is deposited and deforms the apex of pad 2 that extends beyond side walls A. The stress applied by second substrate 3 results in a lateral deformation of pad 2 that presses against side walls A to enhance the tightness. In this way, pad 2 improves the tightness of the channel on all the contact surfaces.

Once second substrate 3 has been deposited, it is advantageous to remove the sacrificial material to release the channel.

The channel is sealed by means of pad 2. Application of an anneal configured to make pad 2 change to molten liquid state transforms the channel into a through channel.

For example, it is possible to melt pad 2 by making a current flow through the latter so that it reaches its melting temperature by Joule effect. In this embodiment, pad 2 is made from electrically conducting material.

It is particularly advantageous to provide for pad 2 to be in the form of a dish to facilitate deformation of the top ends of pad 2 thereby enhancing the tightness. This configuration also makes it possible to limit the quantity of material used to form pad 2 and also to be heated to release the channel.

In advantageous manner, the dimensions of pad 2 and the cross-section of the channel are configured so that opening of the channel is obtained only when the pressure difference in the channel between the two sides of pad 2 reaches a threshold value. Below this threshold value, the wettability forces that exist in the molten metal forming pad 2 are not sufficient to open the valve formed by pad 2.

In other words, in spite of the temperature increase of pad 2 for the latter to reach its melting temperature, its dimensions (cross-section and thickness) mean that it keeps its trap function even in liquid state. A sufficient thrust pressure has to be applied to displace the material in liquid state thereby achieving opening of the channel.

The greater the thickness of pad 2 along the longitudinal axis of the channel, the higher the pressure required to open the channel. The larger the cross-section of the channel, the lower the pressure required to open the channel. The higher the temperature, the lower the pressure required to open the channel. As an alternative or as a complement, opening of the channel can be obtained by means of a rod passing through the molten material.

1-19. (canceled)

20. Method for fabricating an electronic device comprising the following successive steps:
providing a first substrate made from silicon of (100), (110) or (111) orientation, from a material of III-IV type or from a material of II-VI type, provided with at least one salient metal pad, and providing a second substrate;
fixing the first substrate with the second substrate, the at least one salient metal pad forming a blocker configured to come into contact with the second substrate when the second substrate reaches a threshold position with respect to the first substrate;
performing an anneal of the metal pad so as to melt the at least one salient metal pad and eliminate the blocker.

21. Method for fabricating according to claim 20, wherein the first substrate is fixed to the second substrate by means of a spacer and when fixing of the first substrate with the second substrate is performed, the at least one salient metal pad is arranged to block the movement of a surface of the first substrate with respect to the second substrate at a predefined separating distance in a direction perpendicular to said surface of the second substrate.

22. Method for fabricating according to claim 21, wherein the at least one salient metal pad is formed on a first electrode and wherein the anneal transforms the at least one salient metal pad into an additional electrode electrically connected to the first electrode.

23. Method for fabricating according to claim 21, comprising a compression step of the spacer when fixing of the first substrate with the second substrate takes place so as to arrange the second substrate in contact with at least one salient metal pad.

24. Method for fabricating according to claim 20, wherein when fixing the first substrate with the second substrate, the at least one salient metal pad is arranged to block movement of the first substrate with respect to the second substrate in a direction parallel to a surface of the first substrate supporting the second substrate.

25. Method for fabricating according to claim 24, wherein the at least one salient metal pad is formed on an electric contact, the anneal transforming at least one salient metal pad into an additional electric contact and wherein an electronic component is fixed to the first substrate and is electrically connected to the first substrate by means of the additional electric contact.

26. Method for fabricating according to claim 24, wherein the first substrate is fixed to the second substrate by means of a spacer, wherein the first substrate, the spacer and the second substrate define at least one lateral groove, and wherein when fixing the first substrate with the second substrate, the at least one salient metal pad is arranged to block movement of the first substrate with respect to the second substrate in a direction parallel to a surface of the first substrate supporting the second substrate, the at least one salient metal pad preventing insertion of a wire-like element in the lateral groove, the anneal transforming the at least one salient metal pad before a wire-like element is inserted in the lateral groove.

27. Method for fabricating according to claim 26, wherein the at least one salient metal pad is formed on an electric track, the anneal transforming the at least one salient metal pad into an electric contact, and wherein the wire-like element is electrically conducting and is electrically connected to the electric track by means of the electric contact.

28. Method for fabricating according to claim 20, wherein a wire-like element is installed on the first substrate between two metal pads so that the two metal pads block movement of the wire-like element in a direction parallel to a surface of the first substrate supporting the wire-like element and wherein when annealing of the two metal pads is performed, the molten material partially covers the wire-like element by capillarity.

29. Method for fabricating according to claim 28, wherein a fixing layer is deposited on the wire-like element and the metal material after the annealing step to secure the wire-like element with the first substrate.

30. Method for fabricating according to claim 28, wherein the wire-like element is installed on a support and the first substrate blocks the wire-like element against the support, the wire-like element being blocked during the annealing step.

31. Method for fabricating according to claim 20, wherein the first substrate is fixed to the second substrate by means of a spacer and when fixing of the first substrate with the second substrate is performed, the at least one metal pad is constrained between the first and second substrates, and wherein the spacer, the first substrate and the second substrate define a channel sealed off by the at least one salient metal pad, the annealing step making the at least one salient metal pad change to molten state to open the channel.

32. Electronic device comprising:
a first substrate made from silicon of (100), (110) or (111) orientation, from a material of III-IV type or from a material of II-VI type, provided with at least one salient metal pad;
a second substrate fixed to the first substrate by a layer of polymer material, the first substrate being mounted movable with respect to the second substrate so as to allow movement of the second substrate with respect to a surface of the first substrate;
wherein the at least one salient metal pad is a blocker configured to prevent movement of the first substrate with respect to the second substrate beyond a threshold position, the at least one salient metal pad being formed from a material having a melting temperature that is lower than the degradation temperature of the polymer material layer.

33. Electronic device according to claim 32, wherein the layer is an adhesive layer to be polymerised, the adhesive layer to be polymerised allowing sliding of the first substrate with respect to the second substrate, the at least one salient metal pad having a melting temperature that is higher than the polymerisation temperature of the layer.

34. Electronic device according to claim 32, wherein the first substrate is fixed to the second substrate by means of a spacer, the first substrate, the spacer and the second substrate defining at least one lateral groove and wherein the at least one salient metal pad prevents insertion of a wire-like element in the lateral groove.

35. Electronic device according to claim 32, wherein the first substrate comprises an electric contact covered by the at least one salient metal pad, the at least one salient metal pad being formed from a material having a lower melting temperature than the melting temperature of the material forming the electric contact.

36. Electronic device according to claim 32, wherein the first substrate comprises at least two salient metal pads separated by a wire-like element, the at least two salient metal pads being formed from a material having a melting temperature that is lower than the degradation temperature of the material forming the wire-like element.

37. Electronic device according to claim 32, wherein the first substrate is fixed to the second substrate by means of a spacer made from polymer material, the first substrate, the spacer and the second substrate defining a closed cavity, the second substrate forming the cover capping the cavity and the at least one salient metal pad preventing the second substrate from moving towards the first substrate.

38. Electronic device according to claim 37, wherein the second substrate is fixed to the first substrate by means of a spacer that is deformable in a direction perpendicular to the surface of the first substrate, the at least one salient metal pad forming an end-of-travel stop to restrain movement of the second substrate in the direction perpendicular to the surface of the first substrate.
